(19) United States
(12) Patent Application Publication
(10) Pub. No.: US 2010/0175911 A1
(43) Pub. Date: Jul. 15, 2010

(54) High-Speed Two-Layer and Multilayer Circuit Boards

(76) Inventor: Ralph Morrison, Pacifica, CA (US)

Correspondence Address: COURTNEY STANIFORD & GREGORY LLP, 10001 N. De Anza Blvd., Suite 300, Cupertino, CA, 95014, US

(21) Appl. No.: 12/354,243

(22) Filed: Jan. 15, 2009

(51) Int. Cl. H05K 1/00; H05K 3/00

(52) U.S. Cl. 174/250; 29/829

(57) ABSTRACT

Devices and methods are described for high-speed two layer and multilayer circuit boards. A device comprises a single circuit board or a circuit board made by laminating several two layer circuit boards. The device comprises mounting pads attached to the circuit board. The device comprises trace arrays that electrically couple the mounting pads. The trace arrays include a first trace array attached to a first side of each circuit board layer and a second trace array attached to a second side of each circuit board layer. Each trace array comprises conductive traces, and the conductive traces are arranged so each signal trace is positioned between combinations of ground traces and power traces to control the characteristic impedance of each logic or signal path. The arrays on the layers of the board are interconnected by vias to form a pseudo ground and power plane.

### TECHNICAL FIELD

The disclosure herein relates generally to printed circuit boards used in electronics to mount and interconnect components such as integrated circuits, resistors, capacitors, connectors and the like.

### BACKGROUND

The first electronic circuit boards provided a means to mount electronic components and interconnect the components using insulated wires that were stripped and tinned on both ends. To limit the hand labor required in assembly, methods were developed to make electrical connections by etching or depositing copper directly on an insulated circuit board; this technique remains in use for assembling circuit boards and components. These circuit boards are now referred to as printed wiring boards (PWBs) or printed circuit boards (PCBs). The material typically used to make circuit boards is a glass weave impregnated with an epoxy resin. Plated copper pads are formed on the circuit boards, and components are soldered onto these pads. The copper pads are interconnected by conductors that are called traces. The interconnecting traces supply electrical paths between components for analog and digital signals. Power is supplied using separate traces or from conducting planes. Conducting planes supply power and provide a return path for logic signals.

TTL and early CMOS logic circuits worked well using point-to-point wiring techniques on the two surfaces of a board, where the two surfaces of a board are the first and second sides of the circuit board, also referred to as the upper and lower surfaces of the circuit board. Over time the circuit trace count grew as digital circuits became more complex. Designers were forced to go to wire-wrap techniques to provide the needed number of interconnections. As the digital logic speeds increased further this approach was generally not sufficient to control crosstalk and radiation. The solution was to return to using traces on circuit boards but use a laminate construction where ground and/or power plane layers could be added. With these added conductor layers the logic trace count could be increased and board radiation and crosstalk could be controlled. Most advanced digital logic boards are typically constructed using a minimum of four circuit layers where logic traces are intermixed with conducting surfaces dedicated to ground and power.

Advances in integrated circuit performance have made it necessary to treat logic traces as transmission lines. This has forced designers and board manufactures to control the characteristic impedance of every logic transmission. This implies tight control of trace width, trace thickness, trace to trace spacing and trace to conductor plane spacing. Designers must decide if these transmission lines need to be terminated to achieve the desired level of signal integrity.

The development of circuit boards has proceeded along a well defined path. To increase the trace count, control characteristic impedance and supply power, designers can now specify boards with over sixty conducting layers. They can design with traces that are a few millimeters wide and separated by a few millimeters. Vias (plated through holes) that interconnect traces on different layers can be built with aspect ratios of ten to one, and hole diameters can be as small as 1 millimeter. The vias can be hidden or buried. Some of the board layers are dedicated to ground and power planes separated by insulation that is under 1 millimeter in thickness. Many boards that use microprocessors now use a four layer design.

### INCORPORATION BY REFERENCE

Each patent, patent application, and/or publication mentioned in this specification is herein incorporated by reference in its entirety to the same extent as if each individual patent, patent application, and/or publication was specifically and individually indicated to be incorporated by reference.

### BRIEF DESCRIPTION OF THE DRAWINGS

FIG. 1 is a two-sided circuit board with logic traces, under an embodiment.

FIG. 2 is a two-sided circuit board with interconnected signal traces, under an embodiment.

### DETAILED DESCRIPTION

Devices and methods are described for high-speed circuit boards, where the term “high speed” is used herein to refer to fast rise and fall times. A device comprises a circuit board. The device comprises mounting pads attached to the circuit board. The device comprises trace arrays that electrically couple the mounting pads. In an embodiment the trace arrays include a first trace array attached to a first side of the circuit board and a second trace array attached to a second side of the circuit board. Each trace array comprises conductive traces, and the conductive traces are arranged so each signal trace is positioned between ground traces or power traces in any combination. One example embodiment includes a signal trace located between a ground and a power trace.

The devices and methods described herein provide a way to use conventional board manufacturing technology to build a two-layer board that will replace many four-layer or even six-layer board designs. The circuit board of an embodiment automatically provides control of characteristic impedance for all signal or logic traces, without the use of conventional ground and power planes, a configuration that controls characteristic impedance, limits crosstalk, limits susceptibility and radiation to name a few advantages. The circuit board includes vias used to interconnect ground and power traces to provide a pseudo ground and power plane.

In the following description, numerous specific details are introduced to provide a thorough understanding of, and enabling description for, embodiments of the circuit board. One skilled in the relevant art, however, will recognize that these embodiments can be practiced without one or more of the specific details, or with other components, systems, etc. In other instances, well known structures or operations are not shown, or are not described in detail, to avoid obscuring aspects of the disclosed embodiments.

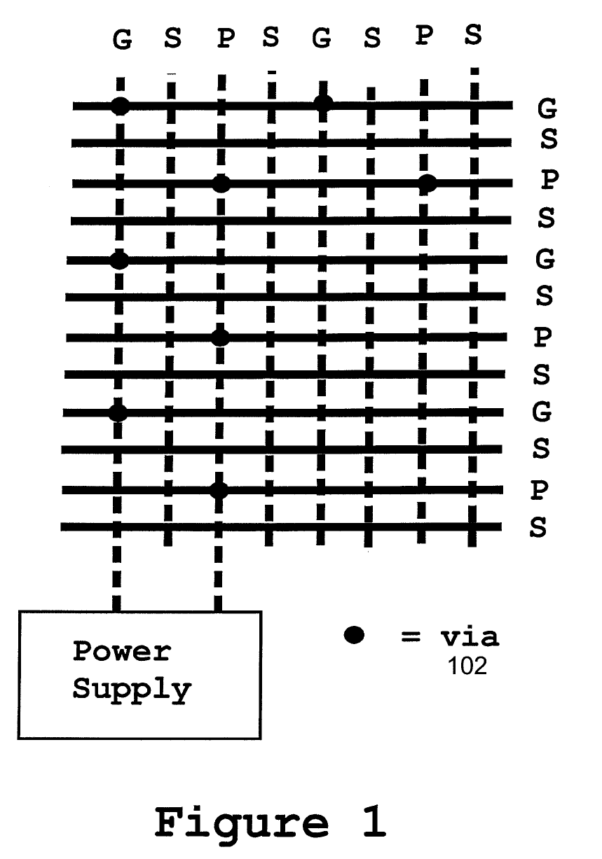

The circuit board of an embodiment places an array of traces on the two sides of a printed circuit board intended primarily for logic operations. FIG. 1 is a two-sided circuit board 100 with logic traces G/SIP, under an embodiment. The circuit board 100 includes a horizontal trace array (solid lines) on an upper or first surface of the circuit board 100, where the horizontal trace array includes traces oriented horizontally. The circuit board 100 includes a vertical trace array (dashed lines) on a lower or second surface of the circuit board 100, where the vertical trace array includes traces oriented vertically. The trace array can be alternatively referred to as a grid or trace grid. The traces of each trace array are oriented approximately parallel to each other, but the embodiment is not so limited.

The circuit board of an alternative embodiment includes a vertical trace array on an upper surface of the circuit board, and a horizontal trace array on a lower surface of the circuit board. The circuit board of another alternative embodiment includes a horizontal trace array on an upper surface of the circuit board, and includes another horizontal trace array on a lower surface of the circuit board. The circuit board of yet another alternative embodiment includes a vertical trace array on an upper surface of the circuit board, and includes another vertical trace array on a lower surface of the circuit board.

The traces of the horizontal trace array of the circuit board 100 of an embodiment are assigned to ground (G), signal (S) (or logic), and power (P) in the sequence GSPS. The sequence of an embodiment is a repeating sequence as appropriate to a number of traces in the trace array. For example, a trace sequence can be GSPSGSPS. Likewise, the traces of the vertical trace array of the circuit board of an embodiment are assigned to ground (G), signal (S) (or logic), and power (P) in the sequence GSPSGSPS, for example. The trace sequence GSPSGSPS may repeat as appropriate to a number of traces in the trace array (e.g., GSPSGSPSGSPS). Trace arrays such as GSGSPSPSGSGSPSPSGSGS are also possible. Regardless of trace orientation, the signal traces are used to interconnect signals (logic) between the components mounted on the circuit board. The ground and power traces are used to connect power and ground to all components on the circuit board and to provide the return path for all logic and signal transmission lines. For clarity the example circuit board 100 shows all possible signal traces, but in many applications many of the traces may be omitted.

The circuit board 100 includes a pattern of vias 102 that connect ground and power traces on the two surfaces of the circuit board. The traces, when connected by vias, form a pseudo ground/power plane that reflects external electromagnetic fields and supplies power to the active components on the circuit board.

A logic transmission line is formed by a triplet of traces comprising a signal trace between any combination of ground and power trace. Therefore, each logic transmission line of the circuit board is formed by a triplet of traces (e.g., GSP, PSG, GSG, PSP etc.). Thus, two logic transmission lines can be run in parallel on the circuit board using a trace sequence PSGSP, where the two transmission lines share a common ground trace. This trace geometry controls the characteristic impedance of both logic paths. This geometry also limits cross coupling between the two signals by controlling the fields that transport the signals.

As described above, each signal is carried on the circuit board of an embodiment by a triplet of traces or triplet conductor geometry that defines or forms a logic transmission line. The characteristic impedance of each transmission line of an embodiment is controlled by trace width, trace spacing and trace thickness of the power, signal, and ground leads. In one embodiment, equal trace width and spacing allows the characteristic impedance of the transmission line to be approximately 50 ohms. The trace width, trace spacing and size of via holes can thus be reduced to increase trace count without loss of performance.

In areas of the circuit board where component mounting pads are located, the trace array may be abandoned. If a component mounting pad is located in an area of the upper surface, for example, the trace array may be abandoned in this area. However, the trace array on the opposite surface (lower surface) is independent of the trace array on the upper surface, so that corresponding area of the lower surface will include a trace array. The ground and power leads on the two surfaces of the circuit board are interconnected by vias to provide current paths around the mounting pad.

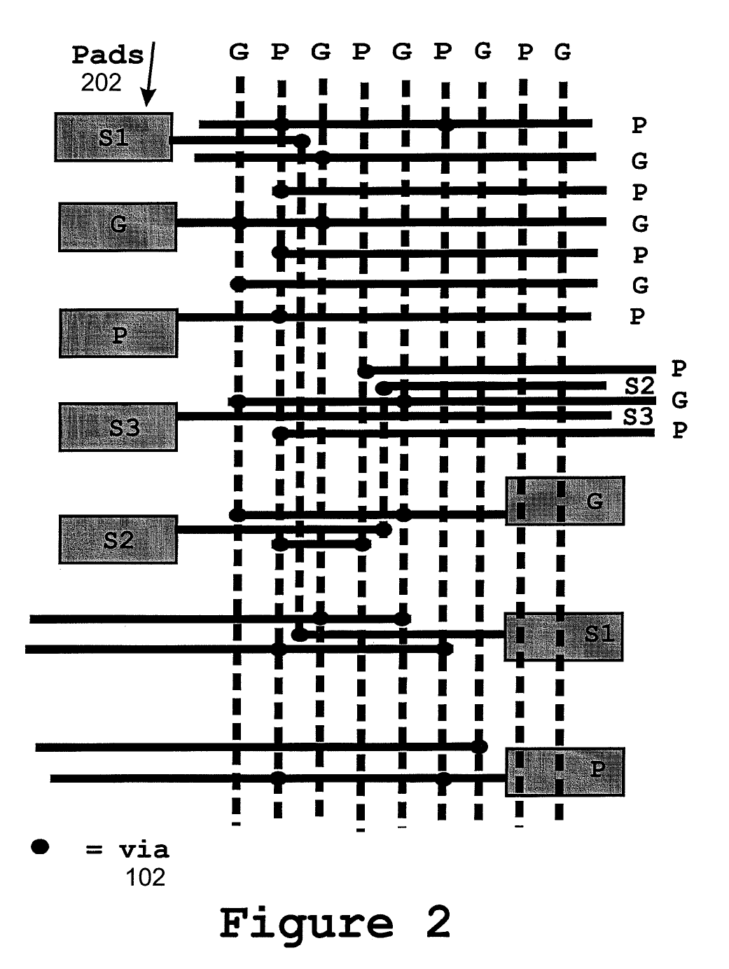

FIG. 2 is a two-sided circuit board 200 with interconnected signal traces G/S/P, under an embodiment. The circuit board 200 includes a horizontal trace array (solid lines) on an upper or first surface of the circuit board 200, where the horizontal trace array includes traces oriented horizontally. The circuit board 200 includes a vertical trace array (dashed lines) on a lower or second surface of the circuit board 200, where the vertical trace array includes traces oriented vertically. The trace array can be alternatively referred to as a grid or trace grid. The traces of each trace array are oriented approximately parallel to each other, but the embodiment is not so limited. The circuit board 200 also includes component mounting pads 202.

The signal traces of this example embodiment include three signal traces designated S1, S2 and S3. In order to change the signal path direction, the signal traces of an embodiment cross to the opposite side of the circuit board. Vias 102 are used to connect the signal, ground and power traces together where the transitions take place. A triplet of vias allows the characteristic impedance of the logic transmission line to be controlled along its entire path, as described above. Signal leads may be omitted if they are not needed. The vias enable traces S1 and S2, for example, to transition vertically by placing a portion of the signal run on the lower surface of the circuit board.

In the preceding detailed description, embodiments of devices are described with reference to specific exemplary embodiments thereof. Various modifications and changes may be made thereto without departing from the broader spirit and scope of the invention as set forth in the claims. The specification and drawings are, accordingly, to be regarded in an illustrative rather than a restrictive sense. Aspects of the devices described herein may be implemented in any of a variety of circuitry. The underlying device technologies may be provided in a variety of component types, e.g., metal-oxide semiconductor field-effect transistor (MOSFET) technologies like complementary metal-oxide semiconductor (CMOS), bipolar technologies like emitter-coupled logic (ECL), polymer technologies (e.g., silicon-conjugated polymer and metal-conjugated polymer-metal structures), mixed analog and digital, to name a few.

It should be noted that any system, method, and/or other components disclosed herein may be described using computer aided design tools and expressed (or represented) as data and/or instructions embodied in various computer-readable media, in terms of their behavioral, register transfer, logic component, transistor, layout geometries, and/or other characteristics. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.). When received within a computer system via one or more computer-readable media, such data and/or instruction-based expressions of the above described components may be processed by a processing entity (e.g., one or more processors) within the computer system in conjunction with execution of one or more other computer programs.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import, when used in this application, refer to this application as a whole and not to any particular portions of this application. When the word “or” is used in reference to a list of two or more items, that word covers all of the following interpretations of the word: any of the items in the list, all of the items in the list and any combination of the items in the list.

The above description is not intended to be exhaustive or to limit the devices and methods to the precise forms disclosed. While specific embodiments of, and examples for, the devices and methods are described herein for illustrative purposes, various equivalent modifications are possible within the scope of the devices and methods, as those skilled in the relevant art will recognize. The teachings of the devices and methods provided herein can be applied to other devices and methods, not only for the devices and methods described above. The elements and acts of the various embodiments described above can be combined to provide further embodiments. These and other changes can be made to the devices and methods in light of the above detailed description.

In general, in the following claims, the terms used should not be construed to limit the embodiments to those specific embodiments disclosed in the specification and the claims, but should be construed to include all embodiments that operate under the claims. Accordingly, the embodiments are not limited by the disclosure, but instead the scope of the embodiments is to be determined entirely by the claims.

While certain aspects of the embodiments are presented below in certain claim forms, the inventor contemplates the various aspects of the embodiments in any number of claim forms. Accordingly, the inventor reserves the right to add additional claims after filing the application to pursue such additional claim forms for other aspects of the embodiments.

What is claimed is:

1. A device comprising:
a circuit board comprising an insulating material;
a plurality of mounting pads attached to the circuit board; and
a plurality of trace arrays that electrically couple the plurality of mounting pads, the plurality of trace arrays including a first trace array attached to a first side of the circuit board and a second trace array attached to a second side of the circuit board, wherein each trace array of the plurality of trace arrays comprises a plurality of conductive traces, wherein the plurality of conductive traces are arranged so each signal trace is positioned between any combination of ground and power trace.

2. The device of claim 1, comprising a transmission line formed by a combination of the signal trace, the ground trace, and the power trace, wherein the signal trace is positioned between the ground trace and the power trace.

3. The device of claim 1, comprising a plurality of vias connecting traces of the first trace array to traces of the second trace array.

4. The device of claim 1, wherein conductive traces of the first trace array have a first orientation relative to a second orientation of the conductive traces of the second trace array.

5. The device of claim 4, wherein the first orientation is approximately the same as the second orientation.

6. The device of claim 4, wherein the first orientation is different than the second orientation.

7. The device of claim 4, wherein the first orientation is approximately horizontal and the second orientation is approximately vertical.

8. The device of claim 1, wherein the plurality of conductive traces are arranged in a sequence of ground trace, signal trace, power trace and signal trace.

9. The device of claim 8, wherein the sequence is repeating.

10. The device of claim 1, wherein the plurality of conductive traces are arranged so the signal trace is positioned between ground and power traces in any combination to control the characteristic impedance of a transmission line formed by the signal trace and the ground and power traces.

11. The device of claim 1, comprising at least one connection between the ground traces and power traces in the first trace array and the ground traces and power traces of the second trace array, wherein the at least one connection forms a pseudo ground plane.

12. The device of claim 1, comprising at least one additional circuit board laminated to the circuit board, the at least one additional circuit board comprising the insulating material and a second plurality of mounting pads attached to the at least one additional circuit board, the at least one additional circuit board comprising a second plurality of trace arrays that electrically couple the second plurality of mounting pads, the second plurality of trace arrays including a third trace array attached to a first side of the at least one additional circuit board and a fourth trace array attached to a second side of the at least one additional circuit board, wherein each trace array of the second plurality of trace arrays comprises a second plurality of conductive traces, wherein the second plurality of conductive traces are arranged so each signal trace is positioned between any combination of ground and power trace, wherein the second plurality of traces is electrically connected to the first plurality of traces using a second plurality of vias.

13. A device comprising:
a circuit board comprising an insulating material;
a plurality of mounting pads attached to the circuit board; and
a plurality of transmission lines attached to a first side and a second side of the circuit board, the plurality of transmission lines electrically coupling the plurality of mounting pads, wherein each transmission line of the plurality of transmission lines comprises a trace triplet including a plurality of conductive traces, wherein the plurality of conductive traces in the trace triplet are arranged so each signal trace is positioned between any combination of ground and power traces.

14. A method comprising:
forming a plurality of mounting pads on a circuit board; and
forming a plurality of trace arrays on the circuit board that electrically couple the plurality of mounting pads, the plurality of trace arrays formed to include a first trace array attached to a first side of the circuit board and a second trace array attached to a second side of the circuit board, wherein each trace array of the plurality of trace arrays is formed to comprise a plurality of conductive traces arranged so each signal trace is positioned between any combination of ground and power traces.

15. The method of claim 14, wherein forming the plurality of traces comprises forming a transmission line through a combination of the signal trace, the ground trace, and the power trace, wherein the signal trace is positioned between the ground trace and the power trace.

16. The method of claim 14, comprising connecting traces of the first trace array to traces of the second trace array using a plurality of vias.

17. The method of claim 14, comprising connecting conductive traces of the first trace array to have a first orientation relative to a second orientation of the conductive traces of the second trace array.

18. The method of claim 17, wherein the first orientation is approximately horizontal and the second orientation is approximately vertical.

19. The method of claim 14, comprising arranging the plurality of conductive traces in a sequence of ground trace, signal trace, power trace and signal trace.

20. The method of claim 14, comprising controlling a characteristic impedance of the signal trace and the power trace by arranging the plurality of conductive traces so the signal trace is positioned between the ground trace and the power trace.

21. The method of claim 14, forming at least one connection between the ground traces and power traces in the first trace array and the ground traces and power traces of the second trace array, wherein the connection forms a pseudo ground plane.

22. The method of claim 14, comprising at least one additional circuit board laminated to the circuit board, the at least one additional circuit board comprising the insulating material and a second plurality of mounting pads attached to the at least one additional circuit board, the at least one additional circuit board comprising a second plurality of trace arrays that electrically couples the second plurality of mounting pads, the second plurality of trace arrays including a third trace array attached to a first side of the at least one additional circuit board and a fourth trace array attached to a second side of the at least one additional circuit board, wherein each trace array of the second plurality of trace arrays comprises a second plurality of conductive traces, wherein the second plurality of conductive traces are arranged so each signal trace is positioned between any combination of ground and power trace, wherein the second plurality of traces is electrically connected to the first plurality of traces using a second plurality of vias.
